(19) United States
(12) Patent Application Publication
(10) Pub. No.: US 2016/0341773 A1
(43) Pub. Date: Nov. 24, 2016

(54) METHOD FOR CLEAR DELINEATION OF WHOLESALE AND RETAIL ENERGY USAGE AND ACTIVITY INVOLVING ENERGY STORAGE DEVICES

(71) Applicant: POWERTREE SERVICES, INC., SAN FRANCISCO, CA (US)

(72) Inventors: Stacey Reineccius, San Francisco, CA (US); Franklin Gobar, San Rafael, CA (US)

(21) Appl. No.: 15/144,546

(22) Filed: May 2, 2016

Related U.S. Application Data
(60) Provisional application No. 62/163,317, filed on May 18, 2015.

(51) Int. Cl. G01R 22/06

(52) U.S. Cl. CPC G01R 22/06

(57) ABSTRACT

Systems and methods for isolated energy measurement are disclosed. A net current between a first point of a circuit and a second point of the circuit is detected based at least in part on a magnitude and a direction of a current provided by a first current transformer coupled to the first point and a magnitude and a direction of a current provided by a second current transformer coupled to the second point. The first current transformer has a first polarity and the second current transformer has a second polarity that is opposite to the first polarity. A voltage of the circuit between the first point of the circuit and the second point of the circuit is detected. A measured energy usage of the circuit between the first point and the second point is determined based on the detected net current and the detected voltage.

### RELATED APPLICATION

This application claims the benefit under 35 U.S.C. §119(e) of U.S. Provisional Application No. 62/163,317 filed May 18, 2015, which is incorporated by reference herein in its entirety.

### TECHNICAL FIELD

The present disclosure relates to techniques for measuring electrical energy.

### BRIEF DESCRIPTION OF THE DRAWINGS

FIG. 1 illustrates a block diagram in which the present systems and methods may be implemented.

FIG. 2 is a schematic diagram illustrating one example of a current transformer.

FIG. 3 is block diagram illustrating one embodiment of present systems and methods.

FIG. 3A is block diagram illustrating another embodiment of the present systems and methods.

FIG. 3B is block diagram illustrating yet another embodiment of the present systems and methods.

FIG. 4 illustrates an example of a system in which the present systems and methods may be implemented.

FIG. 5 illustrates another example of a system in which the present systems and methods may be implemented.

FIG. 6 is a flow diagram of a method for measuring electrical energy.

FIG. 7 is a flow diagram of another method for measuring electrical energy.

FIG. 8 depicts a block diagram of a computer system suitable for implementing the present systems and methods.

### DETAILED DESCRIPTION

A detailed description of systems and methods consistent with embodiments of the present disclosure is provided below. While several embodiments are described, it should be understood that the disclosure is not limited to any one embodiment, but instead encompasses numerous alternatives, modifications, and equivalents. In addition, while numerous specific details are set forth in the following description in order to provide a thorough understanding of the embodiments disclosed herein, some embodiments can be practiced without some or all of these details. Moreover, for the purpose of clarity, certain technical material that is known in the related art has not been described in detail in order to avoid unnecessarily obscuring the disclosure.

The present systems and methods describe various techniques for isolating circuits with multiple inputs and/or multiple outputs so that appropriate measurements can be acquired of where (which input/output, for example), in which direction, when, and how much energy is used. For example, the present systems and methods describe various techniques for creating a known boundary between retail and wholesale electrical metering operations. In one embodiment, a system involves the use of reverse polarized current transformers (CTs) configured to provide a net current (with magnitude and direction) to a current sensor of a single meter. This use of reverse polarized CTs allows for the isolated measurement of energy of equipment placed between the two CTs (e.g., a forward polarized CT at an input and a reversed polarized CT at an output of a generation device or battery). In one embodiment, the present disclosure may be applied to measuring retail energy activity separately from wholesale energy activity in equipment connected at a single service delivery point to an electrical grid.

The present disclosure relates to a process of installing and operating energy storage systems in electrical grid applications or other areas where differentiated electrical utilization tracking use would be beneficial.

Electric meters are designed for single-input single-output (SISO) systems. Traditionally, electrical power has been provided by large power plants and delivered to customers through expansive electrical distribution grids. Electrical meters (e.g., load meters) are placed between the customer and the electrical distribution grid and customers are charged at some rate for the electrical power that they consumed (i.e., as measured by the electrical meter). Accordingly, retail electrical meters, as they are referred to, are designed for one-way (from the power plant to the consumer) power measurement.

With the introduction of consumer level power generation systems (e.g., renewable energy generation systems such as wind and solar generation systems) consumers have the ability to become net electrical producers rather than net electrical consumers. As a result, the net electric meter (NEM) was introduced, which measures the net electrical energy used based on the amount of electrical energy consumed by the consumer (added to the meter) and the amount of electrical energy produced by the consumer (subtracted from the meter).

Although the use of a NEM in this scenario provides measurement of the net electrical energy consumed, the NEM does not measure the energy that was produced by the renewable energy generation system and consumed at the consumer premise. Accordingly, it would be beneficial to measure the energy produced by the renewable energy generation source and/or the total energy consumed by the consumer.

The introduction of electrical storage devices (e.g., batteries) further complicates the ability to accurately and effectively measure electrical power due to various issues such as double counting and/or the capturing/not capturing of round trip efficiency differences. These issues are presented in the context of the following electrical configurations.

In one configuration, an electrical energy storage device may be located in parallel with an on-site load and on-site electrical energy generation, all behind a meter, which is the primary retail utility. In this configuration the electrical energy storage device may be used for applications such as load levelling (See U.S. Pat. No. 8,350,521). In this configuration, loads may be much larger than the capacity of the electrical energy storage device and onsite generation. In this configuration, all energy and power is treated as retail power and all value streams are derived from such retail applications.

In another configuration, an electrical energy storage device may be located in series to an on-site load and on-site generation, all behind a meter, which is the primary retail utility. In this configuration the electronic energy storage device may be used for applications such as backup power, and load levelling (See U.S. Pat. No. 8,350,521). In this configuration, loads may NOT be larger than the capacity of the electrical energy storage device. In this configuration, all energy and power is treated as retail power and all value streams are derived from such retail applications.

In yet another configuration, an electrical energy storage device may be located in series to an on-site load and on-site generation, all behind a wholesale meter, which is in series behind a retail meter. The retail meter is the primary retail utility. In this configuration, the electrical energy storage device may be used for applications such as backup power, and load levelling (See U.S. Pat. No. 8,350,521). In this configuration, loads may NOT be larger than the capacity of the electrical energy storage device and the onsite generation. In this configuration, all energy and power flow through the retail meter and the wholesale meter and are credited in the appropriate direction of flow. Depending on the application this may be used for load leveling, demand response, and on-premises backup power. Energy measured in the wholesale meter is ALSO measured in the retail meter which may also be a net energy meter (NEM).

Applicants have recognized that the above approaches result in numerous disadvantages and limit opportunities for variations in measurement, energy usage tracking, and billing/reimbursing for energy usage. Some of the disadvantages or limitations include: double measurement of energy for a single purpose which may lead to confusion and additional expense; representation of round trip efficiency (RTE) losses as retail charges, and not identifying them as RTE losses but mixing with actual end use retail loads; lack of knowledge of actual performance of an energy storage subsystem; and prevention of dual use (aka stacked value streams) from being achieved by preventing operations in wholesale energy markets requiring clear and defined wholesale energy and power measurement with concurrent or time interleaved retail activities.

The above listed limitations result in a limitation of supportable business models due to regulatory complexity which prevents the useful implementation in an economic fashion. These limits are imposed due to the lack of clear measurement and identification of the energy storage activity.

Based on the foregoing, Applicants have recognized that there exists a need for a simple, accurate techniques to avoid unneeded cost and complexity and to provide a clear and simpler procedure for an isolated measurement of the operation of an electrical energy storage device and/or electrical energy generation device in question. Applicants propose systems, methods, and embodiments to provide improve measurement, tracking, and/or other benefits.

At least one embodiment disclosed herein provides an advantage including utilizing pre-existing standardized metering and a plurality of current transformers. At least one embodiment disclosed herein provides an advantage including remaining compatible with a wide variety of available metering equipment including pre-existing installations that can easily be enhanced based on the present disclosure. At least one embodiment disclosed herein provides an advantage including allowing a simple configuration and installation. At least one embodiment disclosed herein provides an advantage including an ability to uniquely distinguish between retail and wholesale energy usage. At least one embodiment disclosed herein provides an advantage including an ability to uniquely measure and identify RTE losses in an energy storage system. At least one embodiment disclosed herein provides an advantage including that little or no modification to existing utility or grid operator control systems, policies or methods of metering or settling are required to support the application.

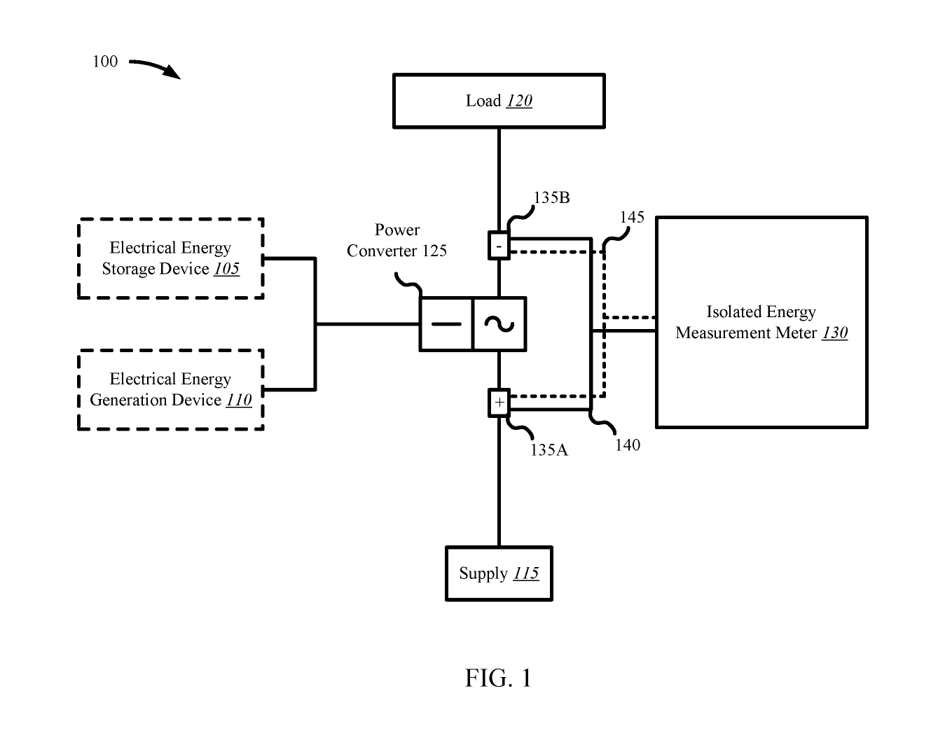

Referring now to the figures, FIG. 1 illustrates a block diagram 100 in which the present systems and methods may be implemented. An electrical energy storage device 105 and/or an electrical energy generation device 110 may be located between an electrical supply 115 (e.g., a distribution grid that is connected to a power plant) and a load 120 (e.g., one or more devices that consume electrical energy).

Examples of the electrical energy storage device 105 include batteries, electrochemical batteries, fuel cells, capacitors, super capacitors, electromechanical batteries, electromagnetic batteries, and/or electrothermal batteries, mechanical or gravity storage, compressed air, etc. Examples of the electrical energy generation device 110 include solar panels, wind turbines, water turbines, steam turbines, geothermal, etc. In one example, the electrical energy storage device 105 may be a lithium based battery and the electrical energy generation device 110 may be a solar panel or an array of solar panels with associated power electronics.

The electrical energy storage device 105 and/or the electrical energy generation device 110 may be coupled to the supply 115 and to the load 120 via a power converter 120. Electrical energy storage devices 105, such as batteries, typically store direct current (DC) electrical energy. Similarly, electrical energy generation devices, such as solar cells, typically generate/produce DC electrical energy. The supply 115, on the other hand, typically provides alternating current (AC) electrical energy. Similarly, loads 120 are typically configured to consume AC electrical energy. AC circuits are incompatible with DC circuits. Accordingly, there is a need to convert electrical energy back and forth between AC and DC circuits. The power converter 125 provides conversion of the electrical energy between the AC and the DC sides (AC→DC converter and DC→AC inverter, for example).

The supply 115 may supply electrical energy to both the load 120 and the electrical energy storage device 105 (and/or the electrical energy generation device 110). In the usual scenario, the supply 115 provides electrical energy directly to the load 120. However, with the addition of the electrical energy storage device 105 and/or the electrical energy generation device 110, the supply 115 may provide electrical energy to something other than the load 120 (from the electrical energy storage device 105, for example). Similarly, the load 120 may receive electrical energy from something other than the supply 115 (from the electrical energy storage device 105 and/or the electrical energy generation device 110, for example). As noted above, typical single path meters (e.g., consumptions only meters, net electric meters (NEM)) are unable to accurately measure/meter/account for multipath options. While a meter at the supply 115 could measure total consumption or net consumption (with a NEM meter, for example), such metering cannot meter/measure/account for the interactions between the electrical energy storage device 105/electrical energy generation device 110 and the load 120.

In some cases, it may be desirable to create a wholesaler business between the supply 115 and the load 120 (a retail end user, for example). In one example, the load 120 may represent an electric car charging station where end users pay retail rates for charging up their electric vehicles. In that case that the wholesaler supplies the load 120 with electrical energy from an electrical energy storage device 105 (e.g., a battery) and/or an electrical energy generation device 110 (e.g., solar panels), such electrical energy could not be properly measured using a meter at the supply 115. Accordingly, new measuring techniques are needed for measuring the energy usage of an isolated circuit (i.e., an isolated circuit that includes more than one electrical path, that includes a non-linear electrical element, and/or that includes one or more of a battery and/or a generator).

The disclosed systems and methods allow for isolated energy measurement of a multipath circuit. A set of reverse polarity current sensors 135A and 135B are coupled together such that if the same current passes through both current sensors 135A and 135B the output of the respective current sensors 135A and 135B cancel each other out to result in a zero net current. For example, connection (e.g., wire) 140 connects to a first terminal of both the current sensors 135A and 135B and connection (e.g., wire) 145 connects to a second terminal of both the current sensors 135A and 135B so that any value created by the first current sensor 135A has a reverse polarity with respect to the second current sensor 135B. It is understood that the effect of reverse polarity current sensors can be realized by placing the current sensors in opposite configurations and wiring common terminals together (a single signed channel, for example), by placing the current sensors in the same configuration and wiring opposite terminals together (a single signed channel, for example), or by wiring each current transformer 235A, 235B to a separate input, measuring each current transformer 235A, 235B separately within the meter as one or more channels (a single signed channel or 2 unsigned channels, each representing one direction of current flow, for example). In the case that the current transformers are wired separately to the isolated energy measurement meter 130, the netting of the current flows may be accomplished via software inside the metering device (e.g., the isolated energy measurement meter 130) such that flows are summed (or subtracted, depending on the wiring configuration)and a report of the net is provided. In some cases, this embodiment may be beneficial as it allows for subordinate individual flows to be measured and reported. It is appreciated that although one option may be described in a particular example or embodiment, any of the options considered above can be used interchangeably as they create the same results.

An isolated energy measurement meter 130 senses the resulting net current of the reverse polarity current sensors 135A and 135B and measures electrical energy based on the net current of the reverse polarity current sensors 135A and 135B (and an isolated circuit voltage measurement (not shown), for example).

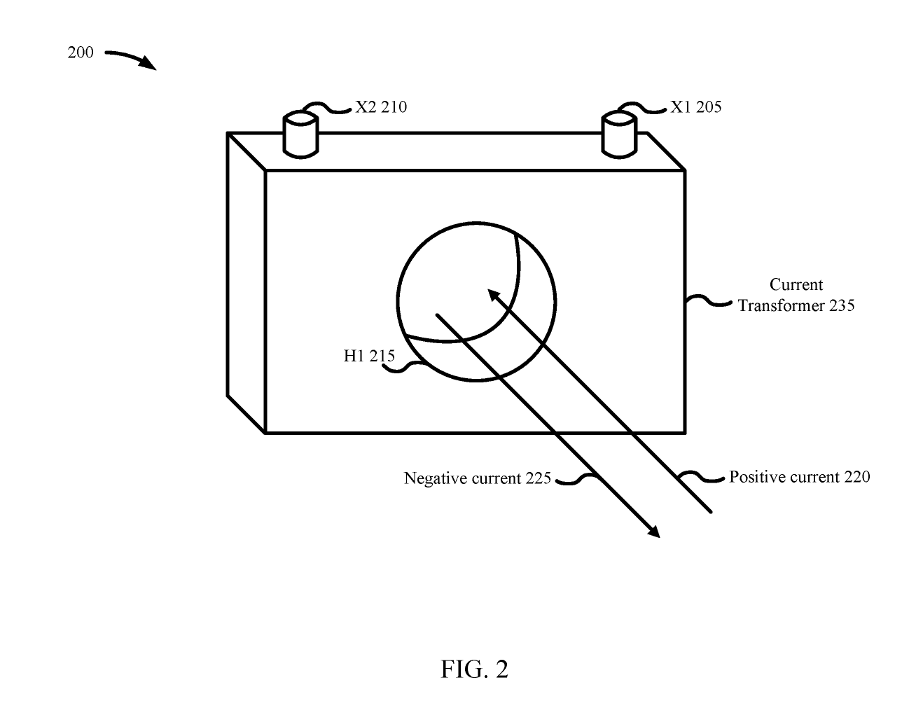

FIG. 2 is a schematic diagram 200 illustrating one example of a current transformer 235. The current transformer 235 may be one example of the current sensor 135 illustrated in FIG. 1. The current transformer 235 includes a primary coil and a secondary coil. AC current passes through the primary coil through opening H1 215. A positive current 220 through H1 215 creates a positive alternating magnetic field in a core which induces a positive alternating current in the secondary coil resulting in a positive current between terminals X1 205 and X2 210. Alternatively, a negative current 225 through H1 215 creates a negative alternating magnetic field in the core which induces a negative alternating current in the second coil resulting in a negative current between terminals X1 205 and X2 210 (e.g., a current from X2 210 to X1 205). As can be appreciated from the design of the current transformer 235, reverse polarity can be realized by placing two current transformers 235 in opposite orientation (e.g., so the same current is a positive current 220 through one of the current transformers and a negative current is a negative current 225 through the other current transformer). Alternatively, two current transformers 235 can be placed in the same orientation (e.g., the same current is a positive current 220 through both current transformers 235 or a negative current 225 through both current transformers 235).

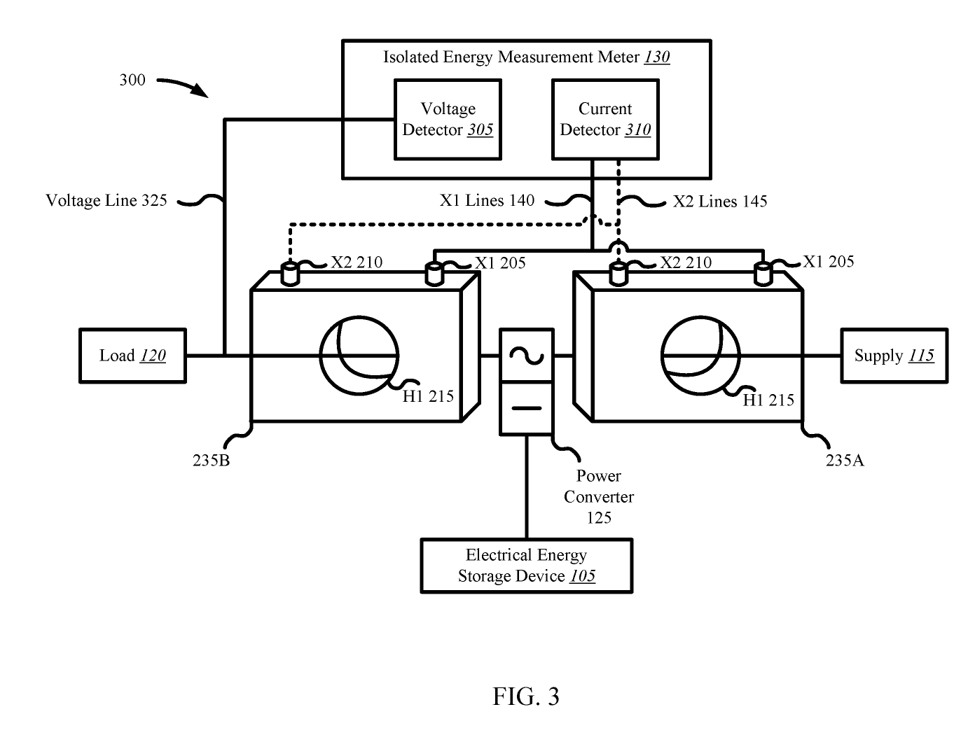

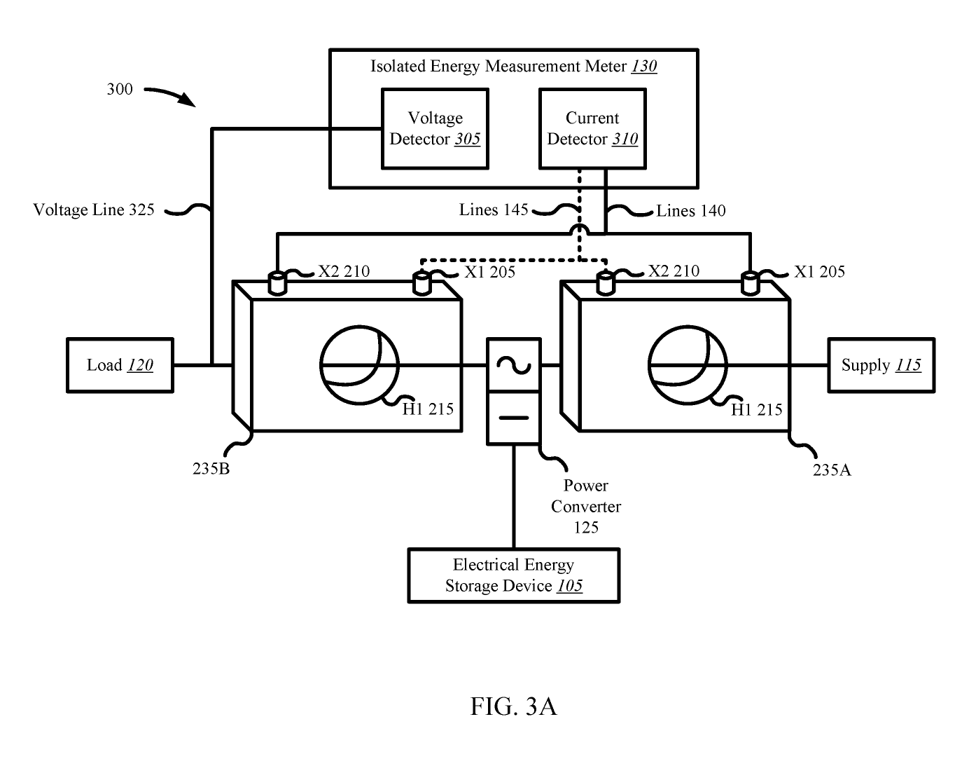

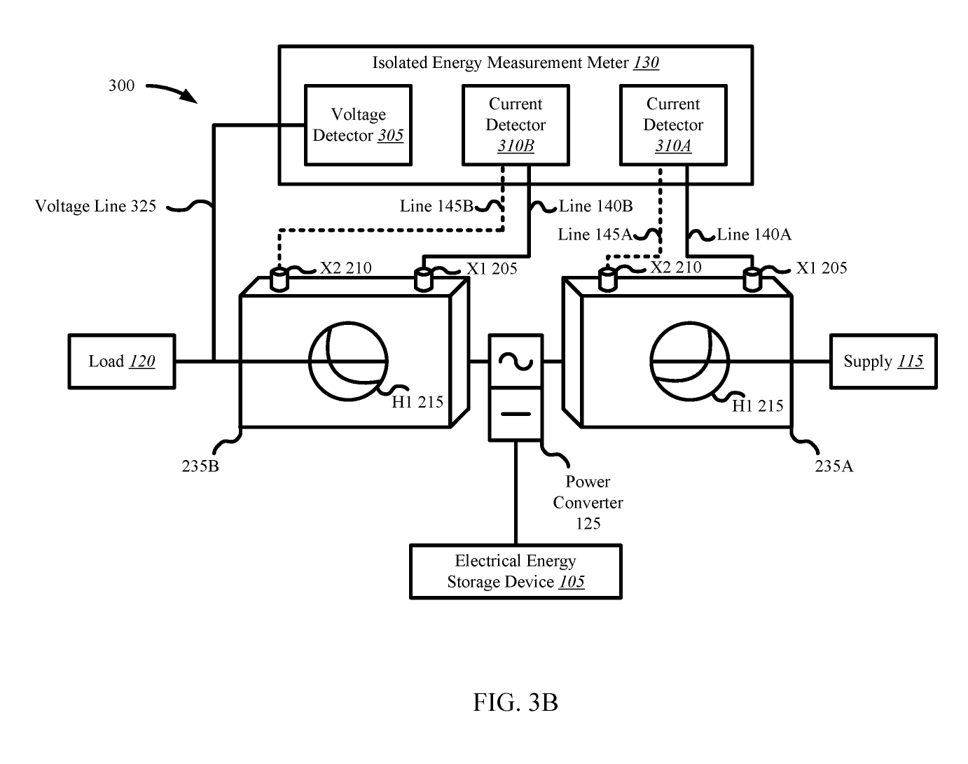

FIG. 3 is block diagram 300 illustrating one embodiment of present systems and methods. As in FIG. 1, the supply 115 provides electrical energy to at least one of the load 120 and the electrical energy storage device 105. It would be beneficial to be able to isolate and measure the amount of electrical energy provided to the electrical energy storage device 105 and the amount of electrical energy provided by the electrical energy storage device 105 to the load 120. For example, it would be beneficial to be able to measure the round-trip efficiency (RTE) associated with the electrical energy storage device 105. In an alternative embodiment (not shown), it would be beneficial to be able to measure how much of the electrical energy used to charge the electrical energy storage device 105 comes from the supply 115 versus coming from a renewable power supply (e.g., solar panel) (connected up near the load 120, for example).

In one embodiment, a first current transformer 235A is placed between the supply 115 and the power converter 125 and a second current transformer 235B is placed between the power converter 125 and the load 120. As illustrated in FIG. 3, the first current transformer 235A may have reverse polarity with respect to the second current transformer 235B because the second current transformer 235B has an opposite orientation with respect to the first current transformer 235A (the two current transformers 235A, 235B face opposite directions, for example). Since the first current transformer 235A and the second current transformer 235B are oriented in opposite directions, the two current transformers 235A, 235B are wired so that the X1 terminals from both current transformers 235A, 235B are connected (i.e., X1 lines 140 (solid lines)) and so that the X2 terminals from both current transformers 235A, 235B are connected (i.e., X2 lines 145 (dotted lines)). The combined X1 lines 140 and the combined X2 lines 145 are connected to respective terminals of a current detector 310. This configuration of two reverse polarity current transformers with the same terminals wired together results in only a net current reading of the isolated circuit (e.g., the circuit between the first and second current transformers 235A, 235B).

For example, when the supply 115 supplies electrical energy (i.e., current at a voltage) directly to the load 120 (i.e., the power converter 125 / electrical energy storage device 105 does not consume any electrical energy), the first current transformer 235A produces a positive current while the second current transformer 235B produces a negative current. When the current through the first current transformer 235A and the second current transformer 235B are the same, then the respective positive and negative currents cancel each other out to result in a net current of zero.

If a portion of the electrical energy from the supply 115 goes to the electrical energy storage device 105, then the second current transformer 235B will produce a smaller negative current because only a portion of the electrical energy that is going through the first current transformer 235A is going through the second current transformer 235B (i.e., it is minus the portion that is going to the electrical energy storage device 105). As a result, the net current experienced by the reverse polarity current transformers 235A, 235B will be net positive (i.e., proportional to the amount of electrical energy that is directed to the electrical energy storage device 105). If, however, a portion of the electrical energy stored in the electrical energy storage device 105 is provided to the load 120, then the second current transformer 235B will produce a higher negative current because all of the electrical energy going to the load 120 will be passing through the second current transformer 235B while only a portion of that electrical energy that is going to the load 120 is coming through the first current transformer 235A (i.e., it is minus the portion that is coming from the electrical energy storage device 105). Accordingly, the reverse polarity current transformers 235A, 235B provide measurement of an isolated section of a circuit.

The isolated energy measurement meter 130 includes a voltage detector 305 that is coupled to the circuit via a voltage line 325. Although the voltage line is shown on the load 120 side, it is understood that it could alternatively be on the supply 115 side without affecting the voltage measurement. The respective X1 lines 140 and X2 lines 145 are coupled to a current detector 310 so as to capture the net current produced by the reverse polarity current transformers 235A, 235B. Using the detected voltage and the detected net current, the isolated energy measurement meter 130 may measure the electrical energy that is consumed/produced in the isolated circuit (i.e., the circuit between the first current transformer 235A and the second current transformer 235B).

In one example, the isolated energy measurement meter 130 may accurately measure round-trip efficiency associated with the electrical energy storage device 105. In another example, the isolated energy measurement meter 130 may allow for precise tracking of what energy is provided to where. In some cases, the information from the isolated energy measurement meter 130 can be used to improve the performance and/or efficiencies that are achievable using electrical energy storage device 105 and/or electrical energy generation devices 110.

In one example, the first current transformer 235A (i.e., the input current transformer) may be the wholesale current transformer 235 that measures current flowing from the grid 115 (i.e., source) towards the load 120. Continuing with the example, the second current transformer 235B (i.e., the output current transformer) may be the wholesale current transformer 235 that measures current flow to load(s) 120. In one embodiment, voltage sense lines are connected to the meter at the load side of the second current transformer 235B. This may ensure proper voltage measurement even in the case of a grid 115 outage or islanding.

In the case that the current transformers 235 are placed in opposite orientations (to create the reverse polarity) the X1 wires 140 from each current transformer 235 are wired together to the same current transformer terminal of the meter (i.e., the current detector 310). Likewise, the X2 wires 145 from each current transformer 235 are wired together to the same current transformer terminal of the meter (i.e., the current detector 310). Alternatively (as illustrated in FIG. 3A), in the case that the current transformers 235 are placed in the same orientations, the X1 wires 140 from one current transformer 235 are wired to the X2 wires 145 of the other current transformer and connected to the same current transformer terminal of the meter (i.e., the current detector 310). Likewise, the X2 wires 145 from one current transformer 235 are wired to the X1 wires 140 of the other current transformer and connected to the same current transformer terminal of the meter (i.e., the current detector 310) (to create the reverse polarity).

Therefore, the current transformers 235A, 235B create differing and opposite current direction which net to a correct net measurement. Specifically, when the current flows from the grid 115 towards the load 120 a positive measurement (i.e. an assumed consumption) is obtained at the first current transformer 235A and then is either stored in the electrical energy storage device 105 or passes through the second current transformer 235B to be used by the load 120 resulting in a negative value being seen at the second current transformer 235B. The wholesale meter 130 connected to these two current transformers 235, as shown, registers the net energy of the isolated circuit (e.g., to the electrical energy storage device 105). On the other hand, if current flows in the opposite direction from the load 120 side towards the grid 115 side then it is first measured at the second current transformer 235B with a positive value (due to the second current transformer 235B being reversed) and then as negative value at the first current transformer 235A.

In one embodiment, if electrical energy is released from the electrical energy storage device 105 towards the grid 115 it must pass via the first current transformer 235A and will be recorded as negative current by the first current transformer 235A. If electrical energy is released from the electrical energy storage device 105 towards the load 120 it must pass via the second current transformer 235B and will be measured with a negative current by the second current transformer 235B. With these characteristics the electrical energy storage device 105 (or any device in a similar position between the two current transformers 235A, 235B) is effectively isolated in its measurement from any other activity in a larger systems and so can be tracked cleanly and distinctly for business and economic settlement purposes.

FIG. 3A is block diagram 300 illustrating another embodiment of the present systems and methods. In FIG. 3A, the second current transformer 235B is oriented in the same direction as the first current transformer 235A. In this configuration, reverse polarity current measurement (single signed channel current measurement, for example) can be achieved by connecting, via lines 140, the X1 terminal from the first current transformer 235A and the X2 terminal from the second current transformer 235B together to the same (e.g., first) current transformer terminal of the meter (i.e., the current detector 310) and connecting, via lines 145, the X2 terminal from the first current transformer 235A and the X1 terminal from the second current transformer 235B together to the same (e.g., second) current transformer terminal of the meter (i.e., the current detector 310).

FIG. 3B is block diagram 300 illustrating yet another embodiment of the present systems and methods. In FIG. 3B, the current from each current transformer 235A, 235B is measured separately (e.g., independently) at the isolated energy measurement meter 130 (e.g., two signed channels or two unsigned channels). For example, the first current transformer 235A may be connected a first current detector 310A with the X1 terminal being connected to the first current detector 310A via line 140A and the X2 terminal being connected to the first current detector 310A via line 145A. Similarly, the second current transformer 235B may be connected a second current detector 310B with the X1 terminal being connected to the second current detector 310B via line 140B and the X2 terminal being connected to the second current detector 310B via line 145B. Although the first and second current transformers 235A, 235B are illustrated as being in opposite orientation, it is appreciated that the first and second current transformers 235A, 235B may be oriented in the same orientation without any wiring changes since the reversing and/or netting computations are performed by the isolated energy measurement meter 130. For example, in the case that the wiring results in one of the current transformers 235 having a reverse polarity with respect to the other current transformer 235, then the isolated energy measurement meter may sum the currents detected by the first current detector 310A and the second current detector 310B to determine the net current flow. In the case that the wiring of the current transformers 235 results in in both of the current transformers having the same polarity, then an inverting of one of the detected currents (i.e., a reversing polarity operation) can be performed by the isolated energy measurement meter 130 prior to the combining (e.g., summing) of the detected currents from the first and second current detectors 305 A, 305B.

The isolated energy measurement module 130 may determine the net current flow based on the detected current from the first current detector 310A and the second current detector 310B. In some cases, detecting the current flow from each current transformer 235 separately allows for individual current transformer 235 measurement and reporting. Further it allows for additional signal processing and/or signal manipulation to improve the net current calculation and/or individual current metrics (e.g., measure total current flow for each current transformer 235 separately). Although, only two current transformers 235 and two current detectors 310 are illustrated, it is appreciated that more than two current transformers 235 can be used, each being connected to a separate current detector 310, so that more that the net current across multiple paths can be determined using a combination of the current flow detected by more than two current detectors 310. For instance, in the case that both an electrical energy storage device 105 and an electrical energy generation device 110 are located within an isolated circuit, as illustrated in FIG. 1, then a third current and/or fourth current transformer 235 can be used on either or both of the electrical energy storage device 105 and the electrical energy generation device 110 to measure the current flow of each device 105, 110 and/or the current flow between the device 105, 110. In some embodiments, the isolated energy measurement meter 130 may calculate sums, differences, averages, etc. of each of the current flows detected by the current detectors 310 to obtain energy measurements for each of the multiple paths (e.g., multiple current transformers).

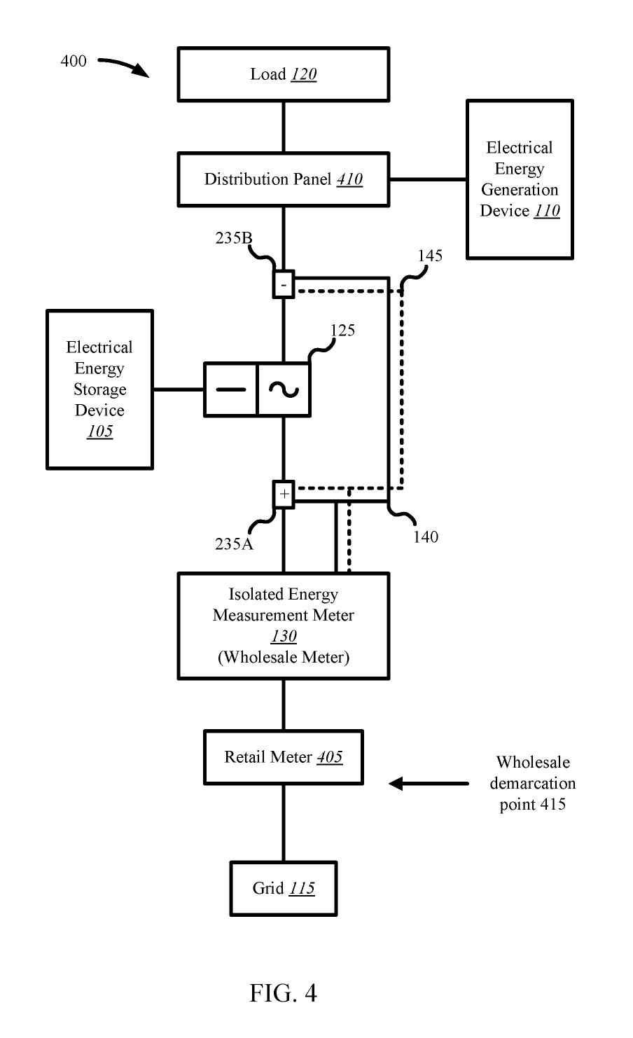

FIG. 4 illustrates an example of a system 400 in which the present systems and methods may be implemented. In one embodiment, the system includes a retail meter 405 (e.g., load meter, possibly retail load meter) from a utility or administrating authority. The retail meter 405 may be placed at the point at which electrical energy is purchased from the grid (e.g., a public utility). In one example, the placement of the retail meter 405 may correspond with the location of the wholesale demarcation point 415. In one embodiment, the system 400 includes an isolated energy measurement meter 130 (e.g., a wholesale revenue meter) that is subsequent to the retail meter 405.

An electrical energy storage device 105 is connected to the circuit via a power converter 125. In an alternative embodiment, the electrical energy storage device may include an AC/DC inverter and/or charger equipment. The electrical energy storage device 105 may include any storage medium (e.g., lithium battery, flow cell, compressed air, gravity fed, stored/pumped hydro, etc.). In one embodiment, the system 400 includes load(s) 120 through electrical distribution and attachment methods. The system 400 further includes a pair of current transformers 235A, 235B. In one example, current transformers 235 are included for each powered leg of electric service (e. g., 120 VAC would have one pair, 240 VAC single phase would have two sets, three phase would have three sets) organized and connected as illustrated in FIG. 4. For example, the current transformers 235 are arranged such that any energy flowing into the energy storage system (e.g., the electrical energy storage device 105 and/or the power converter 125) is measured at the wholesale meter 130 as a positive value regardless of source and such that any energy flowing out of the energy storage system is measured at the wholesale meter 130 as a negative value.

The isolated energy measurement meter 130 (e.g., wholesale meter) is connected to the set of current transformers 235A, 235B. The set of current transformers 235A, 235B are configured to be in a reverse polarity configuration (either by orientation or by wiring). Wires 140 and 145 may connect the set of current transformers 235A, 235B to the isolated energy measurement meter 130 in a way to realize the reverse polarity configuration of the current transformers 235A, 235B. For example, wires 140 may be coupled to the X1 terminals of both current transformers 235A, 235B and wires 145 may be coupled to the X2 terminals of both current transformers 235A, 235B.

As described previously, the electrical energy storage device 105, which is coupled to the circuit via power converter 125, may be between the current transformers 235A, 235B so that the electrical energy movement to and from the electrical energy storage device 105 may be measured. In this example, a distribution panel 410 is included prior to the load 120. The distribution panel 410 may be coupled to an electrical energy generation device 110 (e.g., a solar panel). The electrical energy generation device 110 may provide electrical energy to the load 120, the electrical energy storage device 105, and/or the grid 115. As discussed previously, electrical energy from the electrical energy generation device 110 that is being supplied to the electrical energy storage device 105 may result in a negative current being registered by the isolated energy measurement meter 130. Likewise, electrical energy from the electrical energy storage device 105 that is provided to the load 120 may result in a positive current being registered by the isolated energy measurement meter 130. In this way, the flow of electrical energy to/from the electrical energy storage device 105 may be measured via the isolated energy measurement meter 130.

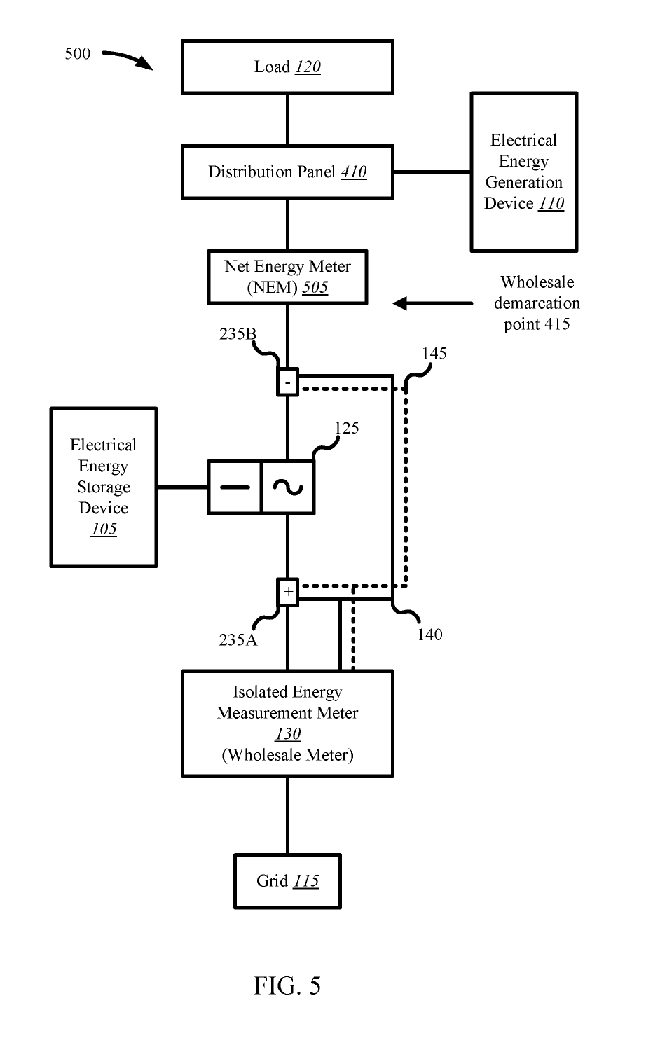

FIG. 5 illustrates another example of a system 500 in which the present systems and methods may be implemented. The system 500 of FIG. 5 is similar to the system 400 of FIG. 4 except that the retail meter 405 has been removed so that the isolated energy measurement meter 130 (e.g., wholesale meter) is connected directly to the grid 115. As illustrated in system 500 the load meter may be located between the isolated circuit and the distribution panel 410 (that is, after/behind the isolated circuit). In one example, the load meter may be a net energy meter (NEM) 505 so as to accommodate the feeding of power from the electrical energy generation device 110 to the grid 115. Since the electrical energy storage device 105 and the isolated circuit are between the NEM 505 and the grid 115, the electrical energy generation device 110 may also feed electrical energy (e.g., power) to the electrical energy storage device 105.

In this configuration, the wholesale demarcation point 415 is located at the NEM 505. As can be appreciated by the described systems and methods, the addition of the isolated energy measurement meter 130 and the associated reverse polarity current transformer configuration may enable measurement of any multipath circuit. Although not shown, a similar set of reverse polarity current transformers 235 and corresponding isolated energy measurement meter 130 may be located on either side of the distribution panel 410 so as to measure the energy flow associated with the electrical energy generation device 110.

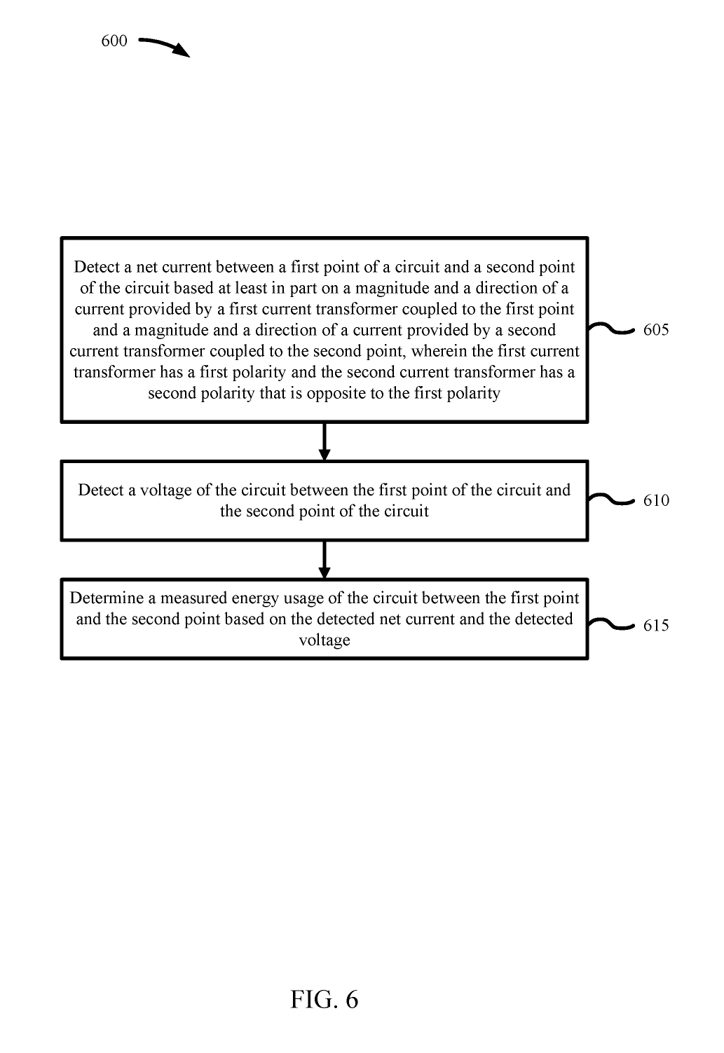

FIG. 6 is a flow diagram of a method 600 for measuring electrical energy. The method 600 is performed by the isolated energy measurement meter 130 illustrated in FIGS. 1, 4, and 5. Although the operations of method 600 are illustrated as being performed in a particular order, it is understood that the operations of method 600 may be reordered without departing from the scope of the method.

At 605, a net current is detected between a first point of a circuit and a second point of the circuit based at least in part on a magnitude and a direction of a current provided by a first current transformer coupled to the first point and a magnitude and direction of a current provided by a second current transformer coupled to the second point. The first current transformer has a first polarity and the second current transformer has a second polarity that is opposite to the first polarity. At 610, a voltage of the circuit is detected between the first point of the circuit and the second point of the circuit. At 615, a measured energy usage of the circuit is determined between the first point and the second point based on the detected net current and the detected voltage.

The operations of method 600 may be performed by an application specific processor, programmable application specific integrated circuit (ASIC), field programmable gate array (FPGA), or the like.

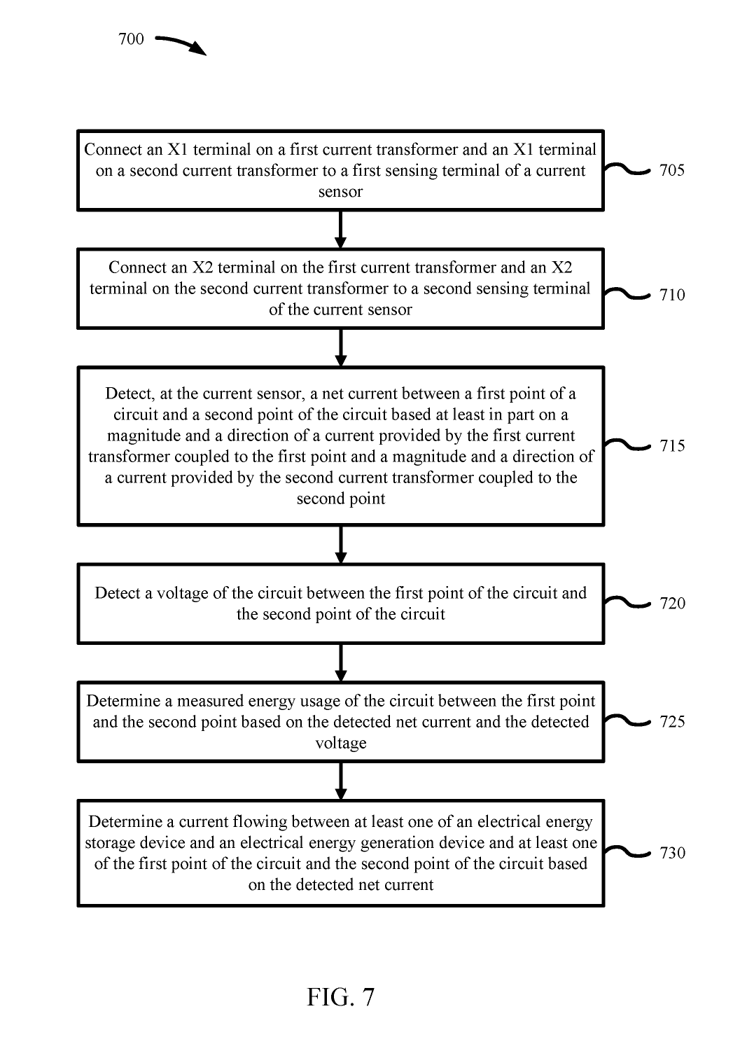

FIG. 7 is a flow diagram of another method 700 for measuring electrical energy. The method 700 is performed by the isolated energy measurement meter 130 illustrated in FIGS. 1, 4, and 5. Although the operations of method 700 are illustrated as being performed in a particular order, it is understood that the operations of method 700 may be reordered without departing from the scope of the method.

At 705, an X1 terminal on a first current transformer and an X1 terminal on a second current transformer are connected to a first sensing terminal of a current sensor. As 710, an X2 terminal on a first current transformer and an X2 terminal on a second current transformer are connected to a second sensing terminal of the current sensor. At 715, a net current is detected at the current sensor between a first point of a circuit and a second point of the circuit based at least in part on a magnitude and a direction of a current provided by a first current transformer coupled to the first point and a magnitude and direction of a current provided by a second current transformer coupled to the second point. The first current transformer has a first polarity and the second current transformer has a second polarity that is opposite to the first polarity. At 720, a voltage of the circuit is detected between the first point of the circuit and the second point of the circuit. At 725, a measured energy usage of the circuit is determined between the first point and the second point based on the detected net current and the detected voltage. At 730, a current flowing between at least one of an electrical energy storage device and an electrical energy generation device and at least one of the first point of the circuit and the second point of the circuit is determined based on the detected net current.

The operations of method 700 may be performed by an application specific processor, programmable application specific integrated circuit (ASIC), field programmable gate array (FPGA), or the like.

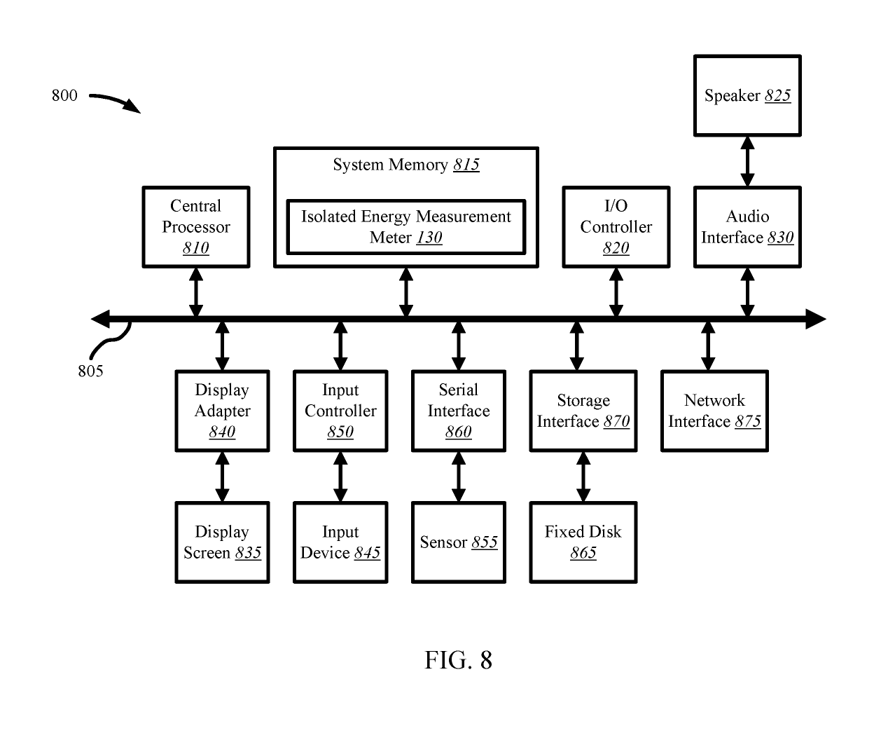

FIG. 8 depicts a block diagram of a computer system 800 suitable for implementing the present systems and methods. Computer system 800 includes a bus 805 which interconnects major subsystems of computer system 800, such as a central processor 810, a system memory 815 (typically RAM, but which may also include ROM, flash RAM, or the like), an input/output (I/O) controller 820, an external audio device, such as a speaker system 825 via an audio output interface 830, an external device, such as a display screen 835 via display adapter 840, an input device 845 (e.g., keyboard, touchpad, touch screen, voice recognition module, etc.) (interfaced with an input controller 850), a sensor 855 (e.g., current sensor) or input device via a serial interface 860, a fixed disk (or other storage medium, for example) 865 via a storage interface 870, and a network interface 875 (coupled directly to bus 805).

Bus 805 allows data communication between central processor 810 and system memory 815, which may include read-only memory (ROM) or flash memory (neither shown), and random access memory (RAM) (not shown), as previously noted. The RAM is generally the main memory into which the operating system and application programs are loaded. The ROM or flash memory can contain, among other code, the Basic Input-Output system (BIOS) which controls basic hardware operation such as the interaction with peripheral components or devices. For example, the isolated energy measurement meter 130 to implement the present systems and methods may be stored within the system memory 815. Applications resident with computer system 800 are generally stored on and accessed via a non-transitory computer readable medium, such as a hard disk drive (e.g., fixed disk 865) or other storage medium.

Storage interface 870, as with the other storage interfaces of computer system 800, can connect to a standard computer readable medium for storage and/or retrieval of information, such as a fixed disk drive (e.g., fixed disk 865). Fixed disk drive may be a part of computer system 800 or may be separate and accessed through other interface systems. Network interface 875 may provide a direct connection to a remote server via a direct network link to the Internet. Network interface 875 may provide such connection using wireless techniques, including digital cellular telephone connection, Cellular Digital Packet Data (CDPD) connection, digital satellite data connection, or the like.

Many other devices or subsystems (not shown) may be connected in a similar manner. Conversely, all of the devices shown in FIG. 8 need not be present to practice the present systems and methods. The devices and subsystems can be interconnected in different ways from that shown in FIG. 8. The operation of a computer system such as that shown in FIG. 8 is readily known in the art and is not discussed in detail in this application. Code to implement the present disclosure can be stored in a non-transitory computer-readable medium such as one or more of system memory 815 or fixed disk 875. The operating system provided on computer system 800 may be iOS®, MS-DOS®, MS-WINDOWS®, OS/2®, UNIX®, LINUX®, or another known operating system.

Moreover, regarding the signals described herein, those skilled in the art will recognize that a signal can be directly transmitted from a first block to a second block, or a signal can be modified (e.g., amplified, attenuated, delayed, latched, buffered, inverted, filtered, or otherwise modified) between the blocks.

Although the signals of the above described embodiment are characterized as transmitted from one block to the next, other embodiments of the present systems and methods may include modified signals in place of such directly transmitted signals as long as the informational and/or functional aspect of the signal is transmitted between blocks. To some extent, a signal input at a second block can be conceptualized as a second signal derived from a first signal output from a first block due to physical limitations of the circuitry involved (e.g., there will inevitably be some attenuation and delay). Therefore, as used herein, a second signal derived from a first signal includes the first signal or any modifications to the first signal whether due to circuit limitations or due to passage through other circuit elements which do not change the informational and/or final functional aspect of the first signal.

Embodiments and implementations of the systems and methods described herein may include various operations, which may be embodied in machine-executable instructions to be executed by a computer system. A computer system may include one or more general-purpose or special-purpose computers (or other electronic devices). The computer system may include hardware components that include specific logic for performing the operations or may include a combination of hardware, software, and/or firmware.

Computer systems and the computers in a computer system may be connected via a network. Suitable networks for configuration and/or use as described herein include one or more local area networks, wide area networks, metropolitan area networks, and/or Internet or IP networks, such as the World Wide Web, a private Internet, a secure Internet, a value-added network, a virtual private network, an extranet, an intranet, or even stand-alone machines which communicate with other machines by physical transport of media. In particular, a suitable network may be formed from parts or entireties of two or more other networks, including networks using disparate hardware and network communication technologies.

One suitable network includes a server and one or more clients; other suitable networks may contain other combinations of servers, clients, and/or peer-to-peer nodes, and a given computer system may function both as a client and as a server. Each network includes at least two computers or computer systems, such as the server and/or clients. A computer system may include a workstation, laptop computer, disconnectable mobile computer, server, mainframe, cluster, so-called “network computer” or “thin client,” tablet, smart phone, personal digital assistant or other hand-held computing device, “smart” consumer electronics device or appliance, medical device, or a combination thereof.

Suitable networks may include communications or networking software, such as the software available from Novell®, Microsoft®, and other vendors, and may operate using TCP/IP, SPX, IPX, and other protocols over twisted pair, coaxial, or optical fiber cables, telephone lines, radio waves, satellites, microwave relays, modulated AC power lines, physical media transfer, and/or other data transmission “wires” known to those of skill in the art. The network may encompass smaller networks and/or be connectable to other networks through a gateway or similar mechanism.

Various techniques, or certain aspects or portions thereof, may take the form of program code (i.e., instructions) embodied in tangible media, such as floppy diskettes, CD-ROMs, hard drives, magnetic or optical cards, solid-state memory devices, a non-transitory computer-readable storage medium, or any other machine-readable storage medium wherein, when the program code is loaded into and executed by a machine, such as a computer, the machine becomes an apparatus for practicing the various techniques. In the case of program code execution on programmable computers, the computing device may include a processor, a storage medium readable by the processor (including volatile and nonvolatile memory and/or storage elements), at least one input device, and at least one output device. The volatile and nonvolatile memory and/or storage elements may be a RAM, an EPROM, a flash drive, an optical drive, a magnetic hard drive, or other medium for storing electronic data. The eNB (or other base station) and UE (or other mobile station) may also include a transceiver component, a counter component, a processing component, and/or a clock component or timer component. One or more programs that may implement or utilize the various techniques described herein may use an application programming interface (API), reusable controls, and the like. Such programs may be implemented in a high-level procedural or an object-oriented programming language to communicate with a computer system. However, the program(s) may be implemented in assembly or machine language, if desired. In any case, the language may be a compiled or interpreted language, and combined with hardware implementations.

Each computer system includes one or more processors and/or memory; computer systems may also include various input devices and/or output devices. The processor may include a general purpose device, such as an Intel®, AMD®, or other “off-the-shelf” microprocessor. The processor may include a special purpose processing device, such as ASIC, SoC, SiP, FPGA, PAL, PLA, FPLA, PLD, or other customized or programmable device. The memory may include static RAM, dynamic RAM, flash memory, one or more flip-flops, ROM, CD-ROM, DVD, disk, tape, or magnetic, optical, or other computer storage medium. The input device(s) may include a keyboard, mouse, touch screen, light pen, tablet, microphone, sensor, or other hardware with accompanying firmware and/or software. The output device(s) may include a monitor or other display, printer, speech or text synthesizer, switch, signal line, or other hardware with accompanying firmware and/or software.

It should be understood that many of the functional units described in this specification may be implemented as one or more components, which is a term used to more particularly emphasize their implementation independence. For example, a component may be implemented as a hardware circuit comprising custom very large scale integration (VLSI) circuits or gate arrays, or off-the-shelf semiconductors such as logic chips, transistors, or other discrete components. A component may also be implemented in programmable hardware devices such as field programmable gate arrays, programmable array logic, programmable logic devices, or the like.

Components may also be implemented in software for execution by various types of processors. An identified component of executable code may, for instance, comprise one or more physical or logical blocks of computer instructions, which may, for instance, be organized as an object, a procedure, or a function. Nevertheless, the executables of an identified component need not be physically located together, but may comprise disparate instructions stored in different locations that, when joined logically together, comprise the component and achieve the stated purpose for the component.

Indeed, a component of executable code may be a single instruction, or many instructions, and may even be distributed over several different code segments, among different programs, and across several memory devices. Similarly, operational data may be identified and illustrated herein within components, and may be embodied in any suitable form and organized within any suitable type of data structure. The operational data may be collected as a single data set, or may be distributed over different locations including over different storage devices, and may exist, at least partially, merely as electronic signals on a system or network. The components may be passive or active, including agents operable to perform desired functions.

Several aspects of the embodiments described will be illustrated as software modules or components. As used herein, a software module or component may include any type of computer instruction or computer-executable code located within a memory device. A software module may, for instance, include one or more physical or logical blocks of computer instructions, which may be organized as a routine, program, object, component, data structure, etc., that perform one or more tasks or implement particular data types. It is appreciated that a software module may be implemented in hardware and/or firmware instead of or in addition to software. One or more of the functional modules described herein may be separated into sub-modules and/or combined into a single or smaller number of modules.

In certain embodiments, a particular software module may include disparate instructions stored in different locations of a memory device, different memory devices, or different computers, which together implement the described functionality of the module. Indeed, a module may include a single instruction or many instructions, and may be distributed over several different code segments, among different programs, and across several memory devices. Some embodiments may be practiced in a distributed computing environment where tasks are performed by a remote processing device linked through a communications network. In a distributed computing environment, software modules may be located in local and/or remote memory storage devices. In addition, data being tied or rendered together in a database record may be resident in the same memory device, or across several memory devices, and may be linked together in fields of a record in a database across a network.

Reference throughout this specification to “an example” means that a particular feature, structure, or characteristic described in connection with the example is included in at least one embodiment of the present disclosure. Thus, appearances of the phrase “in an example” in various places throughout this specification are not necessarily all referring to the same embodiment.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on its presentation in a common group without indications to the contrary. In addition, various embodiments and examples of the present disclosure may be referred to herein along with alternatives for the various components thereof. It is understood that such embodiments, examples, and alternatives are not to be construed as de facto equivalents of one another, but are to be considered as separate and autonomous representations of the present disclosure.

Furthermore, the described features, structures, or characteristics may be combined in any suitable manner in one or more embodiments. In the following description, numerous specific details are provided, such as examples of materials, frequencies, sizes, lengths, widths, shapes, etc., to provide a thorough understanding of embodiments of the disclosure. One skilled in the relevant art will recognize, however, that the disclosure may be practiced without one or more of the specific details, or with other methods, components, materials, etc. In other instances, well-known structures, materials, or operations are not shown or described in detail to avoid obscuring aspects of the disclosure.

It should be recognized that the systems described herein include descriptions of specific embodiments. These embodiments can be combined into single systems, partially combined into other systems, split into multiple systems or divided or combined in other ways. In addition, it is contemplated that parameters/attributes/aspects/etc. of one embodiment can be used in another embodiment. The parameters/attributes/aspects /etc. are merely described in one or more embodiments for clarity, and it is recognized that the parameters/attributes/aspects /etc. can be combined with or substituted for parameters/attributes/etc. of another embodiment unless specifically disclaimed herein.

Although the foregoing has been described in some detail for purposes of clarity, it will be apparent that certain changes and modifications may be made without departing from the principles thereof. It should be noted that there are many alternative ways of implementing both the processes and apparatuses described herein. Accordingly, the present embodiments are to be considered illustrative and not restrictive, and the disclosure is not to be limited to the details given herein, but may be modified within the scope and equivalents of the appended claims.

Those having skill in the art will appreciate that many changes may be made to the details of the above-described embodiments without departing from the underlying principles of the disclosure. The scope of the present disclosure should, therefore, be determined only by the following claims.

1. A system for isolated power metering, comprising:
a first current transformer having a first polarity, wherein the first current transformer is coupled to a first point of a circuit;
a second current transformer having a second polarity, the second polarity being opposite to the first polarity, wherein the second current transformer is coupled to a second point of the circuit; and
an isolated circuit meter coupled to the first current transformer and the second current transformer, the isolated circuit meter sensing a net current between the first point of the circuit and the second point of the circuit based at least in part on a magnitude and a direction of a current provided by the first current transformer and a magnitude and a direction of a current provided by the second current transformer.

2. The system of claim 1, wherein the circuit comprises at least one of an electrical energy storage device and an electrical generation device between the first point and the second point.

3. The system of claim 2, wherein the at least one of the electrical energy storage device and the electrical generation device is connected to the circuit via a power converter.

4. The system of claim 3, wherein the first point of the circuit is connected to an electrical distribution grid and the second point of the circuit is connected to at least one of an electrical load and an electrical generation device.

5. The system of claim 4, wherein the first point of the circuit is connected to the electrical distribution grid via an electrical meter.

6. The system of claim 4, wherein the second point of the circuit is connected to the at least one of the electrical load and the electrical generation device via an electrical meter, wherein the electrical meter comprises a net energy meter (NEM).

7. The system of claim 1, wherein the isolated circuit meter includes a current sensor having a first sensing terminal and a second sensing terminal.

8. The system of claim 7, wherein the first current transformer includes an X1 terminal and an X2 terminal and the second current transformer includes an X1 terminal and an X2 terminal, wherein the X1 terminal on the first current transformer and the X1 terminal on the second current transformer are connected to the first sensing terminal, and wherein the X2 terminal on the first current transformer and the X2 terminal on the second current transformer are connected to the second sensing terminal.

9. The system of claim 1, wherein the meter includes a voltage sensor that is connected to at least one of the first point of the circuit and the second point of the circuit.

10. A method for isolated energy measurement, comprising:
detecting a net current between a first point of a circuit and a second point of the circuit based at least in part on a magnitude and a direction of a current provided by a first current transformer coupled to the first point and a magnitude and a direction of a current provided by a second current transformer coupled to the second point, wherein the first current transformer has a first polarity and the second current transformer has a second polarity that is opposite to the first polarity;
detecting a voltage of the circuit between the first point of the circuit and the second point of the circuit; and
determining a measured energy usage of the circuit between the first point and the second point based on the detected net current and the detected voltage.

11. The method of claim 10, further comprising:
connecting an X1 terminal on the first current transformer and an X1 terminal on the second current transformer to a first sensing terminal of a current sensor; and
connecting an X2 terminal on the first current transformer and an X2 terminal on the second current transformer to a second sensing terminal of the current sensor.

12. The method of claim 10, further comprising:
determining a current flowing between at least one of an electrical energy storage device and an electrical generation device and at least one of the first point of the circuit and the second point of the circuit based on the detected net current, wherein the at least one of the electrical energy storage device and the electrical generation device is between the first point of the circuit and the second point of the circuit.

13. The method of claim 12, wherein detecting the net current comprises detecting a zero net current when a same current flows between the first point of the circuit and the second point of the circuit.

14. The method of claim 12, wherein detecting the net current comprises detecting a positive net current when at least a portion of current flowing from the first point of the circuit is provided to the electrical energy storage device.

15. The method of claim 12, wherein detecting the net current comprises detecting a negative net current when at least a portion of current flowing to the second point of the circuit is provided by the electrical storage device.

16. The method of claim 12, wherein detecting the net current comprises detecting a negative net current when at least a portion of current flowing from the second point of the circuit is provided to the electrical storage device.

17. A non-transitory computer-readable medium having instructions thereon, the instructions being executable by a processor to:
detect a net current between a first point of a circuit and a second point of the circuit based at least in part on a magnitude and a direction of a current provided by a first current transformer coupled to the first point and a magnitude and a direction of a current provided by a second current transformer coupled to the second point, wherein the first current transformer has a first polarity and the second current transformer has a second polarity that is opposite to the first polarity;
detect a voltage of the circuit between the first point of the circuit and the second point of the circuit; and
determine a measured energy usage of the circuit between the first point and the second point based on the detected net current and the detected voltage.

18. The computer-readable medium of claim 17, wherein the instructions to detect the net current comprise instructions executable by the processor to:
detect a current flowing between at least one of an electrical energy storage device and an electrical generation device and at least one of the first point of the circuit and the second point of the circuit, wherein the at least one of the electrical energy storage device and the electrical generation device is between the first point of the circuit and the second point of the circuit.

19. The computer-readable medium of claim 18, wherein the instructions to detect the net current comprise instructions executable by the processor to detecting a zero net current when a same current flows between the first point of the circuit and the second point of the circuit.

20. The computer-readable medium of claim 18, wherein the instructions to detect the net current comprise instructions executable by the processor to detect a positive net current when at least a portion of current flowing from the first point of the circuit is provided to the electrical energy storage device.
